(19) United States
(12) Patent Application Publication
(10) Pub. No.: US 2026/0198276 A1
(43) Pub. Date: Jul. 9, 2026

(54) CHEMICAL SOAK PRECLEAN FOR SELECTIVE METAL FILL AND CHEMICAL ADSORPTION

(71) Applicant: Applied Materials, Inc., Santa Clara, CA (US)

(72) Inventors: Bingqian LIU, Santa Clara, CA (US); Hao ZHUANG, Mountain View, CA (US); Yi XU, San Jose, CA (US); Yu LEI, Belmont, CA (US); Rongjun WANG, Dublin, CA (US)

(21) Appl. No.: 19/013,277

(22) Filed: Jan. 8, 2025

(51) Int. Cl. H01L 21/768; H01L 23/522; H01L 23/528

(52) U.S. Cl. CPC H10W 20/056; H10W 20/076; H10W 20/42; H10W 20/43

(57) ABSTRACT

Embodiments described herein generally relate to semiconductor device fabrication. More specifically, embodiments of the present disclosure relate to methods of removing metal oxides during semiconductor device manufacturing. The method includes performing a first soak process on the semiconductor device structure, forming a metal fill material in at least one feature, and performing a second soak process on the semiconductor device structure. The semiconductor device structure includes at least one feature formed in a dielectric layer of the semiconductor device structure. The first soak process includes flowing a first precursor gas over the at least one feature. The metal fill material is formed by partially filling the at least one feature where a gap region forms between a sidewall of the at least one feature and the metal fill material. The second soak process includes flowing a second precursor gas over the at least one feature and the metal fill material.

### BACKGROUND

### Field

Embodiments described herein generally relate to semiconductor device fabrication. More specifically, embodiments of the present disclosure relate to methods of removing metal oxides during semiconductor device manufacturing.

### Description of the Related Art

Integrated circuits have evolved into complex devices that can include millions of transistors, capacitors, and resistors on a single chip. In the course of integrated circuit evolution, functional density (e.g., the number of interconnected devices per chip area) has generally increased while geometry size (e.g., the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (e.g., DRAM) and logic devices, including both planar and three-dimensional structures. Examples of three-dimensional structures are finFET and MOSFET devices.

In a traditional middle-of-the-line (MOL) interconnect formation process, a feature, such as a via or trench is fabricated in the semiconductor substrate. MOL contacts allow connections between front-end-of-the-line (FEOL) semiconductor structures and back-end-of-the-line (BEOL) interconnects. Contacts with low resistance are desirable in semiconductor devices. However, when a MOL interconnect has a relatively high resistance, a poor connection is created at the MOL interconnect, which reduces the overall performance of the packaged semiconductor structures.

Conventional MOL and BEOL electrical connections, such as contacts, interconnects, and the like, are formed by filling a feature such as a cavity, trench, or via with a conductive material. Then the feature is filled with a metal material to form a metal fill layer that serves as an interconnect between layers of the device. As devices reach the 1.4 nm node and beyond, molybdenum (Mo) is being used to replace tungsten (W) as the material of the metal fill layer due to its lower resistivity inside smaller features. However, after additional MOL or BEOL processing is performed after depositing Mo, process gases, such as nitrogen or ammonia (NH₃), or the gases in the ambient environment, such as O₂ or H₂O, cause nitridation and oxidation of the surfaces of the formed Mo metal fill layer and significantly increase the resistance of the formed interconnect due to the presence of nitrogen or oxygen containing layers formed on exposed surfaces.

Therefore, there is a need in the art for a method that to remove metal oxides and/or metal nitrides from each feature of the semiconductor device.

### SUMMARY

In a first embodiment, a method of filling a semiconductor device structure is disclosed. The method includes performing a first soak process on the semiconductor device structure, forming a metal fill material in at least one feature, and performing a second soak process on the semiconductor device structure. The semiconductor device structure includes at least one feature formed in a dielectric layer of the semiconductor device structure. The first soak process includes flowing a first precursor gas over the at least one feature. Forming a metal fill material includes the metal fill material partially fills the at least one feature and a gap region is formed between a sidewall of the at least one feature and the metal fill material. The second soak process includes flowing a second precursor gas over the at least one feature and the metal fill material.

In another embodiment, a method of filling a semiconductor device structure is disclosed. The method includes performing a first soak process, forming a metal fill layer, performing a second soak process, and forming a passivation layer on the semiconductor device structure. The semiconductor device structure including a feature formed within a dielectric layer of the semiconductor device. The first soak process includes flowing a first precursor gas over the feature where the first precursor gas is tungsten hexafluoride (WF₆). Forming the metal fill layer within the feature where the metal fill material partially fills the feature and a gap region is formed between a sidewall of the feature and the metal fill material. The second soak process including flowing a second precursor gas over the feature and the metal fill material, the second precursor gas including WF₆ or molybdenum (V) chloride (MoCl₅). Forming a passivation layer over the feature where the passivation layer is disposed over the metal fill material and within the gap region.

In another embodiment, a semiconductor device structure is disclosed. The semiconductor device structure including a first dielectric layer disposed over a substrate, a second dielectric layer disposed over the first dielectric layer, a feature formed through the first dielectric layer and the second dielectric layer, an electrical connection disposed within the feature, a metal fill material disposed over the electrical connection, and a passivation layer embedding the metal fill material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a schematic top view of a multi-chamber processing system, according to one or more embodiments.

FIG. 2 is a flow diagram depicting a method of forming an electrical connection of a semiconductor structure, according to one or more of the embodiments.

FIGS. 3A, 3B, 3C, 3D, 3E, 3F, 3G, and 3H illustrate views of various stages of forming an electrical connection of a semiconductor structure, according to one or more embodiments.

FIG. 4 is a plot illustrating the normalized change in thickness of the molybdenum oxide (MoOx) film or molybdenum (Mo) film during an etch proves by tungsten hexafluoride (WF₆).

FIG. 5A is a graph illustrating the etch rate by molybdenum (V) chloride (MoCl₅) on molybdenum oxides (MoOx) and Molybdenum (Mo) at various temperatures.

FIG. 5B is a graph illustrating the etch rate by tungsten hexafluoride (WF₆) on molybdenum oxides (MoOx) and Molybdenum (Mo) at 300 degrees C.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to semiconductor device fabrication. More specifically, embodiments of the present disclosure relate to methods of removing metal oxides during semiconductor device manufacturing. Middle-of-the-line (MOL) and back-end-of-the-line (BEOL) electrical connections, such as interconnects, and the like are formed by filling a feature such as a cavity, trench, or via with a conductive material that is in contact with an underlying metal layer. During manufacturing, metal oxides may form within the feature of the semiconductor device. To remove the metal oxides before proceeding with fabrication, a preclean chemical soak method is performed to selectively remove metal oxides without damaging walls of the feature. Further, the preclean chemical soak improves surface absorption for silicon (Si), Germanium (Ge), and other similar materials.

After forming the preclean chemical soak, the interconnect is formed by filing feature with a metal material to form a metal fill layer. In one or more embodiments, subsequent BEOL or MOL process gases cause oxidation and/or nitridation of the metal fill layer, increase the resistance of the formed interconnect, and therefore, reduce the performance of the electrical connection. The oxidation (or nitridation) forms a layer of metal oxide (or metal nitride) over and around the metal fill layer. To remove the metal oxide (or metal nitride) from the metal fill layer, a treatment process such as a chemical soak is performed to selectively etch the metal oxide (or metal nitride) from within the feature without etching the sidewalls of the feature. The preclean chemical soak and the chemical soak increase surface absorption, avoid side wall damage, increase resistance, and are capable of reaching the deep structure of the feature.

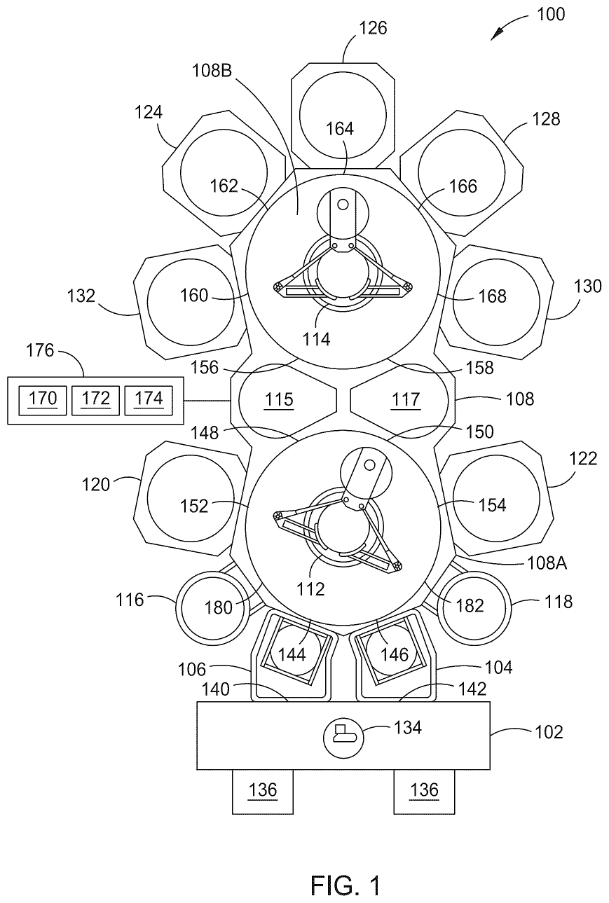

FIG. 1 illustrates a schematic top view of a multi-chamber processing system 100 according to one or more embodiments. The multi-chamber processing system 100 can be used for creating a bottom lateral recess (an etch recess) in a device substrate to anchor a metal material of an MOL or BEOL electrical connection during a chemical mechanical polishing (CMP) process. The multi-chamber processing system 100 generally includes a factory interface 102, load lock chambers 104, 106, a transfer chamber 108 (with a first portion 108A and a second portion 108B) with respective transfer robots 112, 114, holding chambers 115, 117, one or more optional service chambers 116, 118, and processing chambers 120, 122, 124, 126, 128, 130, 132. In one or more embodiments, the first portion 108A of the transfer chamber 108 and the second portion 108B of the transfer chamber 108 are separate transfer chambers. As detailed herein, substrates in the multi-chamber processing system 100 can be processed in and transferred between the various chambers without exposing the substrates to an ambient environment exterior to the multi-chamber processing system 100, for example, an atmospheric ambient environment such as may be present in a fab. The substrates can be processed in and transferred between the various chambers maintained at a low pressure, for example, less than or equal to about 300 Torr, or a vacuum environment without breaking the low pressure or vacuum environment among various processes performed on the substrates in the multi-chamber processing system 100. Accordingly, the multi-chamber processing system 100 may provide for an integrated solution for processing of substrates.

Examples of multi-chamber processing systems that may be suitably modified in accordance with the teachings provided herein include the Endura^{®}, Producer^{®}, or Centura^{®}integrated multi-chamber processing systems or other suitable multi-chamber processing systems commercially available from Applied Materials, Inc., located in Santa Clara, California. It is contemplated that other multi-chamber processing systems (including those from other manufacturers) may be adapted to benefit from aspects described herein.

In the illustrated example of FIG. 1, the factory interface 102 includes a docking station and at least one factory interface robot 134 to facilitate transfer of substrates. The docking station is adapted to accept one or more front opening unified pods (FOUPs) 136. In some examples, each factory interface robot 134 generally includes a blade disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The first portion 108A of the transfer chamber 108 further has respective ports 148, 150 coupled to the holding chambers 115, 117, respective ports 180,182 coupled to one or more optional service chambers 116, 118, and respective ports 152, 154 coupled to processing chambers 120, 122. Similarly, the second portion 108B of the transfer chamber 108 has respective ports 156, 158 coupled to the holding chambers 115, 117 and respective ports 160, 162, 164, 166 coupled to processing chambers 124, 126, 128, 130, 132. The ports 144, 146, 148, 150, 152, 154, 156, 158, 160, 162, 164, 166, 180, 182 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, the transfer chamber 108, the holding chambers 115, 117, one or more optional service chambers 116, 118, and the processing chambers 120, 122, 124, 126, 128, 130, 132 may be fluidly coupled to a gas and pressure control system (not specifically illustrated). The gas and pressure control system can include one or more gas pumps (for example, turbo pumps, cryo-pumps, roughing pumps) gas sources, various valves, and conduits fluidly coupled to the various chambers. In operation, the factory interface robot 134 transfers a substrate from the FOUP 136 through the port 140 or 142 to the load lock chamber 104 or 106. The gas and pressure control system then pumps down the load lock chamber 104 or 106. The gas and pressure control system further maintains the transfer chamber 108 and the holding chambers 115, 117 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108. In some embodiments, one or more optional service chambers (shown as 116 and 118) may be coupled to the transfer chamber 108. The service chambers 116 and 118 may be configured to perform other substrate processes, such as degassing, orientation, substrate metrology, cool down, and the like.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing, the one or more optional service chambers 116, 118 through the respective ports 180, 182, and the holding chambers 115, 117 through the respective ports 148, 150 for holding to await further transfer. Similarly, the transfer robot 114 is capable of accessing the substrate in the holding chamber 115 or 117 through the port 156 or 158 and is capable of transferring the substrate to and/or between any of the processing chambers 124, 126, 128, 130, 132 through the respective ports 160, 162, 164, 166, 168 for processing and the holding chambers 115, 117 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130, 132 can be any appropriate chamber for processing a substrate. In some examples, the processing chamber 120 can be capable of performing an etch process, the processing chamber 122 can be capable of performing a cleaning process, and the processing chambers 126, 128, 130, 132 can be capable of performing respective growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 124, 126, 128, 130, or 132 may be a Volta™ CVD/ALD chamber, Trillium™ ALD chamber, or Encore™ PVD chambers available from Applied Materials of Santa Clara, Calif.

A system controller 176 is coupled to the multi-chamber processing system 100 for controlling the multi-chamber processing system 100 or components thereof. For example, the system controller 176 may control the operation of the multi-chamber processing system 100 using a direct control of the chambers 104, 106, 108, 115, 116, 117, 118, 120, 122, 124, 126, 128, 130, 132 of the multi-chamber processing system 100 or by controlling controllers associated with the chambers 104, 106, 108, 115, 116, 117, 118, 120, 122, 124, 126, 128, 130, 132. In operation, the system controller 176 enables data collection and feedback from the respective chambers to coordinate performance of the multi-chamber processing system 100.

The system controller 176 generally includes a central processing unit (CPU) 170, memory 172, and support circuits 174. The CPU 170 may be one of any form of a general-purpose processor that can be used in an industrial setting. The memory 172, non-transitory computer-readable medium, or machine-readable storage device, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. That is, the computer program product is tangibly embodied on the memory 172 (or non-transitory computer-readable medium or machine-readable storage device). When the computer instruction code is executed by the CPU 170, the CPU 170 controls the chambers to perform processes in accordance with the various methods.

The instructions in memory 172 may be in the form of a program product, such as a program that implements the methods of the present disclosure. In one example, the disclosure may be implemented as a program product stored on a computer-readable storage media for use with a computer system. The program(s) of the program product define functions of the implementations (including the methods described herein). Thus, the computer-readable storage media, when carrying computer-readable instructions that direct the functions of the methods described herein, are implementations of the present disclosure. The system controller 176 is configured to perform methods such as the method 200 stored in the memory 172.

Other processing systems can be in other configurations. For example, more or fewer processing chambers may be coupled to a transfer apparatus. In the illustrated example, the transfer apparatus includes the transfer chambers 108 and the holding chambers 115, 117. In other examples, more or fewer transfer chambers (e.g., one transfer chamber) and/or more or fewer holding chambers (e.g., no holding chambers) may be implemented as a transfer apparatus in a processing system.

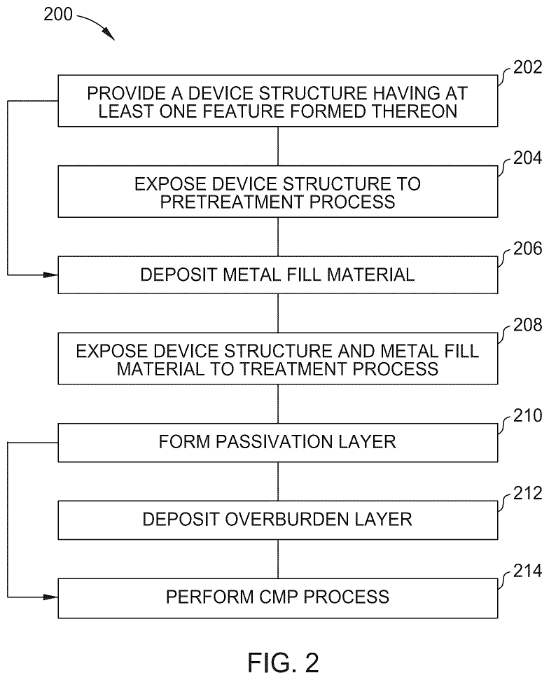

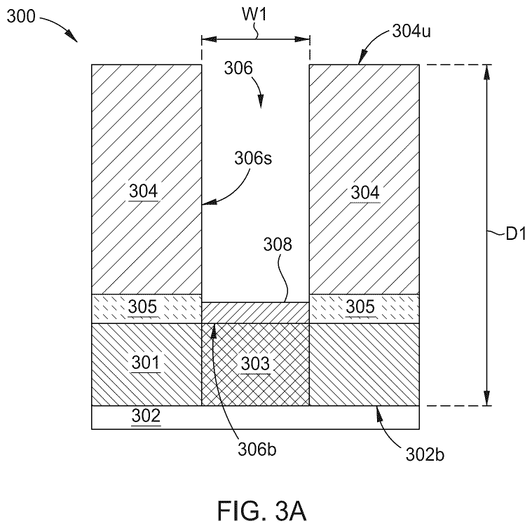

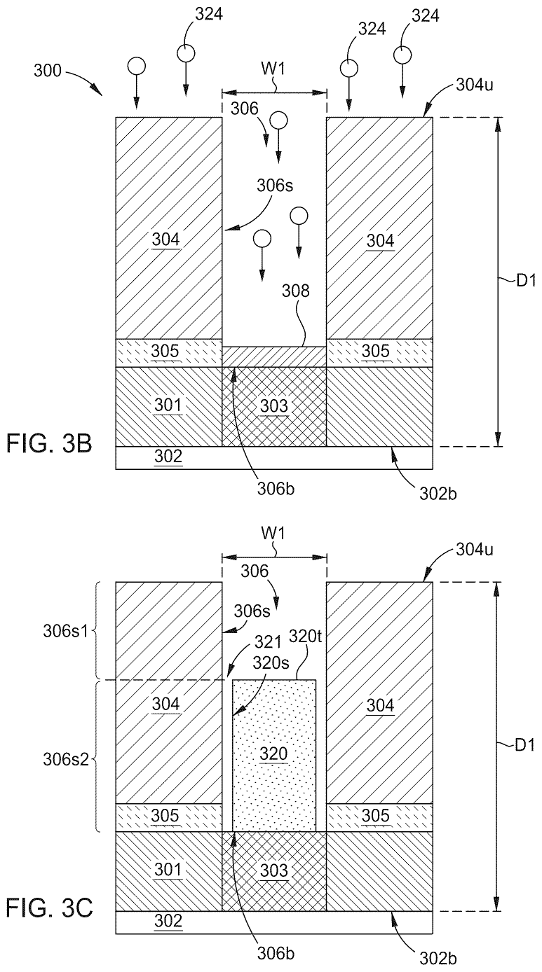

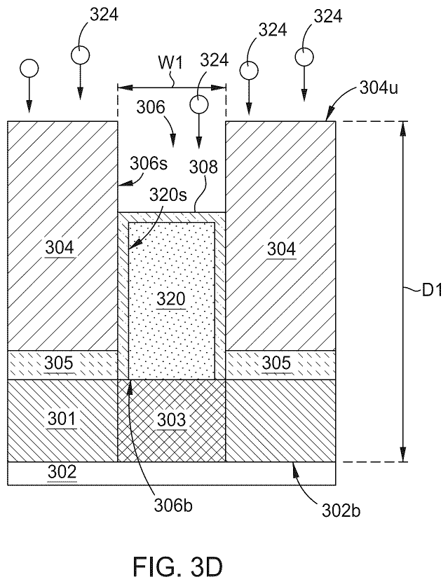

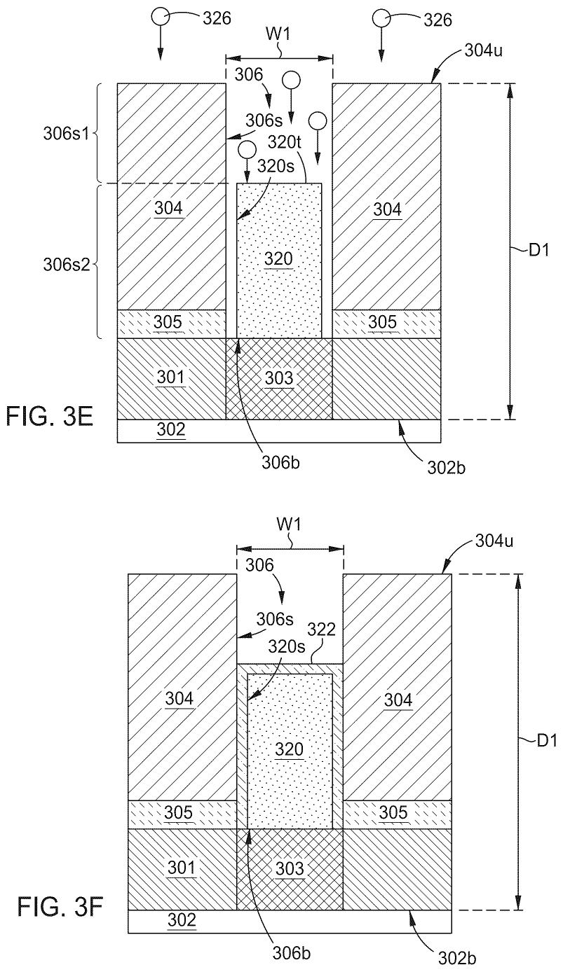

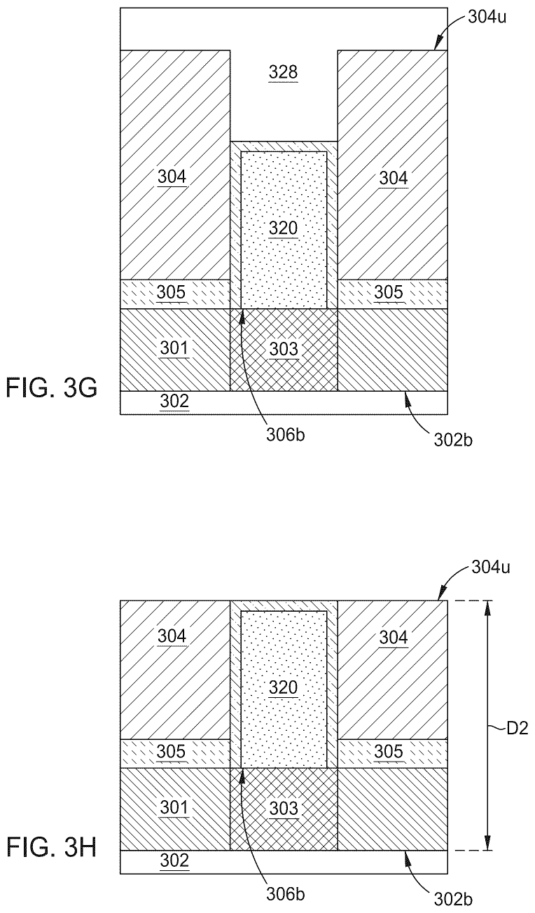

FIG. 2 is a process flow diagram of a method 200 of forming an electrical connection of a semiconductor device structure 300. FIGS. 3A-3H are cross-sectional views of various stages of forming an electrical connection of the semiconductor device structure 300. It should be understood that FIGS. 3A-3H illustrate cross-sectional views of a portion of the semiconductor device structure 300 formed on a device substrate 302 (e.g., a substrate). FIGS. 3A-3H are only partial schematic views of the semiconductor device structure 300, and the semiconductor device structure 300 may contain any number of transistor sections and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein. Method 200 may be performed in a processing chamber (e.g., processing chambers 120, 122, 124, 126, 128, 130, or 132), as shown in FIG. 1.

As shown in FIG. 3A, at operation 202, a semiconductor device structure 300 having at least one feature thereon is provided. The semiconductor device structure 300 includes a device substrate 302 having one or more layers formed thereon, for example, dielectric layers 301 and 304, underlying metal layer 303, and etch stop layer 305 as is shown in FIG. 3A. The device substrate 302 may be or include a bulk semiconductor substrate, a semiconductor-on-insulator (SOI) substrate, or the like, which may be doped (e.g., with a p-type dopant or an n-type dopant) or undoped. In some embodiments, the semiconductor material of the base substrate portion of the device substrate 302 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GaInAs, GaInP, and/or GaInAsP; a combination thereof, or the like. The device substrate 302 may include additional materials, for example, silicide layers, metal silicide layers, metal layers, dielectric layers, etch stop layers, interlayer dielectrics, or a combination thereof.

The device substrate 302 may further include integrated circuit devices (not shown) that are formed in one or more layers below the layers shown in FIGS. 3A-3H. As one of ordinary skill in the art will recognize, a wide variety of integrated circuit devices such as transistors, diodes, capacitors, resistors, the like, or combinations thereof may be formed in and/or on the device substrate 302 to generate the structural and functional requirements of the design for the resulting semiconductor device structure 300.

The dielectric layers 301 and 304, and the etch stop layer 305 are formed over the device substrate 302. In one or more embodiments, the etch stop layer 305 is formed between dielectric layer 301 and dielectric layer 304. The dielectric layer 301 is formed over the device substrate 302 (and the additional layers formed over the device substrate (if any)), the etch stop layer 305 is formed over the dielectric layer 301, and the dielectric layer 304 is formed over the etch stop layer 305. The etch stop layer 305 is sandwiched between the dielectric layers 301 and 304.

The dielectric layers 301 and 304 may include multiple layers. The dielectric layer 304 includes an upper surface 304u or field region. In some embodiments, the dielectric layers 301 and 304 include a dielectric material, such as a low k dielectric (SiCOH), silicon oxide, silicon dioxide (SiO₂), silicon nitride (Si₃N₄), silicon carbide (SiC), silicon oxynitride (SiON), aluminum oxide (Al₂O₃), aluminum nitride (AlN), a combination thereof, or multi-layers thereof. In some embodiments, the dielectric layers 301 and 304 consist essentially of silicon oxide. It is noted that the foregoing descriptors for example, silicon oxide, should not be interpreted to disclose any particular stoichiometric ratio. Accordingly, “silicon oxide” and the like will be understood by one skilled in the art as a material consisting essentially of silicon and oxygen without disclosing any specific stoichiometric ratio. In one or more embodiments, the etch stop layer 305 includes any suitable material, including but not limited, silicon nitride, silicon carbide, metal oxide, or carbon containing, or combinations thereof.

The semiconductor device structure 300 is patterned to form one or more feature(s) 306. The feature 306 may be a high aspect ratio (HAR) feature. In some embodiments, the feature 306 can be selected from, but not limited to, a trench, a via, a hole, a cavity, or a combination thereof. In particular embodiments, the feature 306 is a trench. In other particular embodiments, the feature 306 is a via. In some embodiments, the feature 306 extends from the upper surface 304u of the dielectric layer 304 towards the backside 302b of the device substrate 302. The feature 306 includes sidewall surface(s) 306s that extend from the upper surface 304u to the backside 302b.

In some embodiments, an electrical connection (not shown) is formed within the dielectric layer 301 formed at the bottom of the feature 306. The electrical connection may be an interconnect, a contact structure, or the like that includes the conductive material found in the underlying metal layer 303. The electrical connection is formed in a prior patterning sequence performed prior to forming the dielectric layer 304 and forming feature 306 therein. For example, as shown in FIG. 3A, the electrical connection may be a contact structure that includes a conductive material. The conductive material may be formed of copper (Cu), cobalt (Co), molybdenum (Mo), tungsten (W), tantalum (Ta), titanium (Ti), or ruthenium (Ru), combinations thereof, and/or nitrides thereof. The feature 306 has a first depth “D1” from the upper surface 304u to the backside 302b and a width “W1” between the two sidewall surface(s) 306s. In some embodiments, the depth D1 is in a range of 2 nm to 200 nm. In some embodiments, the width W1 is in a range of 10 nm to 100 nm. In some embodiments, the feature 306 has an aspect ratio (D/W) in a range of 1 to 20.

In some embodiments, as shown in FIG. 3A, the semiconductor device structure 300 may have a metal oxide layer 308 or other contaminants formed on the sidewall surface(s) 306s, the underlying metal layer 303, and/or the bottom surface 306b. In one example, the metal oxide layer 308 is tungsten oxide or aluminum oxide. The semiconductor device structure 300 may be exposed to atmosphere prior to or during processing, which may lead to the formation of the metal oxide layer 308 on the surfaces of the feature 306. For example, if a vacuum break occurs prior to or during the method 200, the vacuum break can lead to the formation of native oxides. In addition, other processes performed prior to or during the method 200 may lead to the formation of additional contaminants or debris on the sidewall surface(s) 306s and the underlying metal layer 303. In other embodiments, the metal oxide layer 308 may not be present on the surfaces of the feature 306 and underlying metal layer 303.

At operation 204, the semiconductor device structure 300 is exposed to a pretreatment process, such as a first soaking process. FIG. 3B illustrates a cross-sectional view of the semiconductor device structure 300 during intermediate stages of manufacturing during operation 204. The pretreatment process of operation 204 can include one or more metal oxide or contamination removal processes for removing the contamination and/or metal oxide layer 308, if the native oxide or contamination is present. The pretreatment process of operation 210 can include one more clean processes. In one or more embodiments, the clean process is a chemical soak where a precursor gas 324 comprising tungsten hexafluoride (WF₆), molybdenum(V) chloride (MoCl₅), or combinations thereof is introduced to the device structure 300 as shown. The soak process may include soaking the semiconductor device structure 300 in a processing chamber at a desired temperature, pressure, and time, such as the processing chambers 120, 122. 124, 126, 128, 130, or 132 as shown in FIG. 1, using a precursor gas 324 (e.g., WF₆). The precursor gas 324 (e.g., WF₆) is flowed into the chamber during a chemical vapor deposition (CVD) method. As shown in FIG. 3B, the precursor gas 324 permeates over the semiconductor device structure 300 such that the precursor gas 324 at least contacts the metal oxide layer 308. The chemical soak removes only the metal oxide layer 308 from the feature 306 (e.g., the chemical soak does not damage or remove portions of the surfaces (e.g., the sidewall surfaces 306s or the bottom surface 306b) of the feature 306).

In one or more examples, the first soak process may be performed at a chamber pressure of between about 1 Torr and about 100 Torr, for example about 5 Torr to about 50 Torr. The first soak process may include flowing the precursor gas in the presence of a carrier gas, such as argon (or another noble gas), at flow rate between about 5 sccm and about 2000 sccm, for example, about 500 sccm to about 1500 sccm. The first soak process may include a purge gas. In one or more embodiments, the purge gas is argon. The first soak process may be performed for a period of time between 1 second and 1500 seconds, such as about 60 seconds to about 180 seconds. The first soak process period of time is dependent on the temperature of the chamber. The first soak process may be performed at a process chamber temperature of between about 200° C. and about 500° C., for example about 200° C. to about 400° C.

At operation 206, as shown in FIG. 3C, the feature 306 is partially filled with a metal fill material 320 by use of selective deposition process at a first deposition rate. FIG. 3C illustrates a cross-sectional view of the semiconductor device structure 300 during intermediate stages of manufacturing corresponding to the operation 206. The metal fill material 320 can be formed by a selective bottom-up deposition process. The metal fill material 320 may be formed by any suitable deposition process such as an atomic layer deposition (ALD) process, a chemical vapor deposition (CVD) process, a hybrid ALD/CVD process, a plasma enhanced ALD (PEALD) process, a plasma enhanced CVD (PECVD) process, or the like. In some embodiments, the metal fill material 320 includes molybdenum (Mo). In other embodiments, the metal fill material 320 can be a metal such as tungsten (W), cobalt (Co), copper (Cu), ruthenium (Ru), or other useful metals. In one example, precursors used during the deposition process may include molybdenum-containing precursors selected from molybdenum chlorides (e.g., MoClₓ [x=2-6]), molybdenum fluorides (MoF₆)). In some embodiments, the molybdenum chloride can be or include molybdenum (II) chloride, molybdenum (III) chloride, molybdenum (IV) chloride, molybdenum (V) chloride, molybdenum (IV) chloride, or a combination thereof. In particular embodiments, the molybdenum chloride precursor can be or include molybdenum (V) chloride that is molybdenum pentachloride (MoCl₅). Suitable examples of the metal containing precursor include Mo(NMe₂)₄, MoCl₅, MoF₆, molybdenum tetramethylheptane-3,5-dionato (Mo(thd)₃), Mo(CO)₆, and the like that are used to form a molybdenum containing layer.

In one example, the metal fill material 320 deposition process includes a CVD process that includes injecting a molybdenum containing precursor (e.g., molybdenum pentachloride (MoCl₅)), hydrogen (H₂) and a carrier gas (e.g., argon (Ar)) into a processing chamber, while maintaining the device substrate 302 disposed within the processing chamber (e.g., the processing chambers represented in FIG. 1) at a temperature in a range of about 300 to 425 °C. In some embodiments, an ampoule temperature of an ampoule that includes the molybdenum containing precursor, which positioned upstream of the processing chamber environment, is maintained at a lower temperature than the temperature within the processing chamber. For example, the ampoule temperature may be maintained in a range of about 60 to 90 °C. In certain embodiments, a pressure within the processing chamber during the deposition process may be maintained in a range of about 5 to 50 Torr.

In one or more embodiments, as shown in FIG. 3C, the feature 306 is partially filled with the metal fill material 320, forming a partially filled feature. In some embodiments, it is desirable to only partially fill the feature 306 due to a low deposition rate commonly found when using a selective deposition process to form a conductive layer. Furthermore, due to the selectivity of the bottom-up deposition process, gaps 321 are formed between the sidewalls 320s of the metal fill material 320 and the sidewall surfaces 306s of the dielectric layer 304. For example, as shown in FIG. 3C, the metal fill material 320 fills a bottom portion 306s2 of the feature 306 such that a gap 321 forms between the sidewall 306s of the feature 306 and the sidewall 320s of the metal fill material 320. The sidewall 306s of the top portion 306s1 remains exposed after operation 206.

The gaps 321 are easily penetrated by ammonia (NH₃) nitrogen (N* or N₂), oxygen (O₂), water (H₂O), or any other processing gas used during subsequent BEOL and MOL processing. In one or more embodiments, subsequent to partially filling the feature 306 with the metal fill material 320, the semiconductor device structure 300 experiences a vacuum break. The vacuum break allows for the semiconductor device structure 300 to be exposed to an ambient environment such that the feature 306 and the gaps 321 are exposed to oxygen (O₂), water (H₂O), or any other gas or compound in the ambient environment. As shown in FIG. 3D, the penetration of the gaps 321 by processing gases or the ambient environment causes oxidation and/or nitridation of the exposed surfaces of the metal fill material 320. In FIG. 3D, this is represented as a metal oxide layer 308. For example, if the metal fill material 320 comprises Mo, after exposure to oxygen, the metal fill material 320 may be surrounded by a molybdenum oxide layer (MoOₓ). Stated otherwise, the gaps 321 may be filled and a top surface 320t of the metal fill material 320 may be covered with the metal oxide layer 308 such as a MoOₓ layer (or any other oxidation or nitridation layer). However, as noted above, the MoOₓ layer (e.g., the oxidation/nitridation) of the metal fill material 320 increases the resistance of an interconnect formed of the metal fill material 320.

At operation 208, as shown in FIG. 3D, the semiconductor device structure 300 and the metal fill material 320 are exposed to a treatment process, such as a second soak process. The treatment process can include one or more metal oxide, metal nitride or contamination removal processes for removing the contamination and/or metal oxide layer 308, if the metal oxide or contamination is present. The treatment process of operation 208 can include one more clean processes. In one or more embodiments, the clean process is a chemical soak (e.g., the second soak process) where the precursor gas 324 is a tungsten hexafluoride (WF₆) or molybdenum (V) chloride (MoCl₅). The second soak process may include soaking the semiconductor device structure 300 in a processing chamber at a desired temperature, pressure, and time, such as the processing chambers 120, 122. 124, 126, 128, 130, or 132 as shown in FIG. 1, using the precursor gas 324 (e.g., WF₆ or MoCl₅). The precursor gas 324 (e.g., WF₆ or MoCl₅) is flowed into the chamber during a chemical vapor deposition (CVD) method. In one or more embodiments, WF6 is flowed into the chamber independently (e.g., WF₆ is not coflowed into the chamber with a carrier gas) during the treatment process. In one or more embodiments, MoCl₅ is coflowed into the chamber with a carrier gas (e.g., argon). The MoCl₅ is coflowed into the chamber with a carrier gas at a percent of about 1% to about 10% (e.g., about 1% to about 10% precursor gas is coflowed into the chamber) during the treatment process. As shown in FIG. 3D, the precursor gas 324 permeates over the semiconductor device structure 300 such that the precursor gas 324 at least contacts the metal oxide layer 308 disposed over and around the metal fill material 320. The second chemical soak removes only the metal oxide layer 308 disposed over and around the metal fill material 320 and removes the metal oxide from the feature 306 (e.g., the second chemical soak does not damage or remove portions of the surfaces (e.g., the sidewall surfaces 306s or the bottom surface 306b) of the feature 306). The removal of the metal oxide layer 308 provides a plurality of surfaces of the metal fill material 320 capable for chemical absorption.

In one or more examples, the second soak process may be performed at a chamber pressure of between about 1 Torr and about 100 Torr. For example, the chamber pressure is about 5 Torr to about 50 Torr. The second soak process may include flowing the precursor gas in the presence of a carrier gas, such as argon (or another noble gas), at flow rate between about 5 sccm and about 2000 sccm, such as about 100 sccm to about 500 sccm. The second soak process may be performed for a period of time between 1 second and 1500 seconds, such as about 60 seconds to about 180 seconds. The second soak process may be performed at a process chamber temperature of between about 200° C. and about 500° C., such as 200° C. to about 400° C.

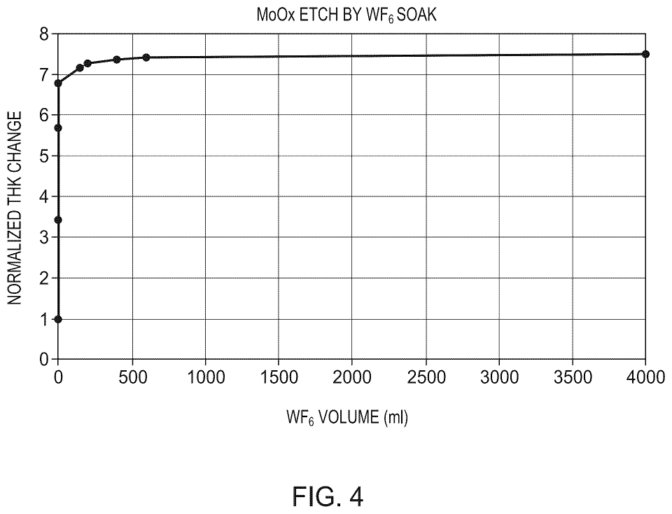

As shown in FIG. 4, the treatment process (e.g., the second chemical soak) using a WF₆ precursor gas etched MoOx using a relatively low volume (ml) of WF₆. The etch thickness changes as the volume of WF₆ is flowed over the semiconductor device structure 300. As shown in FIG. 4, a small volume of WF₆ is capable to etch MoOx. The change in thickness of the MoOx is faster than conventional methods. The flattening of the graph, as shown in FIG. 4, indicates all the MoOx has been etched from the semiconductor device structure 300 by the treatment process (e.g., there is no further etching, indicating the treatment does not etch the metal fill material (Mo) or the sidewalls 306s during the treatment process). Accordingly, the example shown in FIG. 4 indicates the treatment process includes a beneficial selectivity for etching oxides from the metal fill material with a small volume of precursor gas (e.g., with a fast time). It is speculated that this is in part to the isotropic properties of the precursor gas (e.g., WF₆) used in the treatment process.

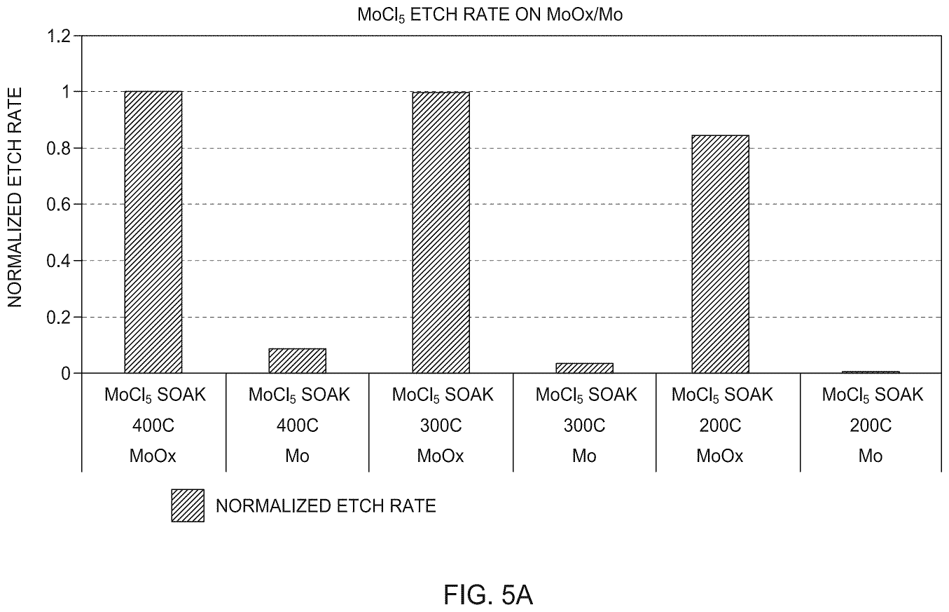

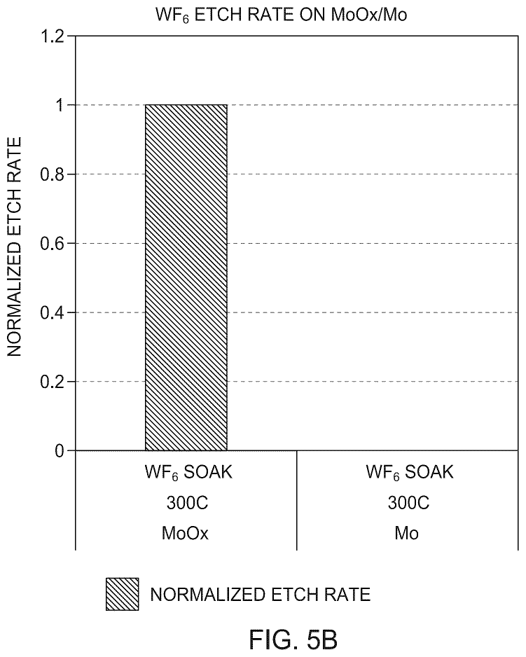

As shown in FIG. 5A, the treatment process (e.g., the second chemical soak) using MoCl₅ was tested under varying temperature conditions. The second chemical soak using MoCl₅. As shown in FIG. 5A, the normalized etch rate (Å/s) of MoOx is greater than the normalized etch rate (Å/s) of Mo at all temperature conditions. The difference in normalized etch rate indicates the selectivity of MoCl₅ during the treatment process. At lower temperatures (e.g., 200° C.) the selectivity of MoCl₅ increases resulting in significant etching of the MoOx and minor etching in the Mo. As shown in FIG. 5B, the treatment process (e.g., the second chemical soak) using WF₆ was tested at 300° C. As shown in the example in FIG. 5B, the normalized etch rate (Å/s) of MoOx and Mo at 300° C. is shown. The Mo is not etched by the WF₆ at 300° C. The examples shown in FIGS. 5A and 5B indicates WF₆ includes a higher etch selectivity for MoOx when compared to MoCl₅.

At operation 210, a passivation layer 322 is formed over the metal fill material 320. As illustrated in FIGS. 3E and 3F, in one or more examples, the passivation layer 322 is formed over the top surface 320t and within the gaps 321. In one or more embodiments, the chemistry of the passivation layer 322 is configured such that the passivation layer 322 prevents nitridation and/or oxidation of the metal fill material 320 while having no effect on the resistance and electrical operation of the semiconductor device structure 300. In one or more embodiments, the passivation layer 322 may include, but is not limited to, a passivation layer 322 containing silicon (Si), a passivation layer 322 containing boron (B), a passivation layer 322 containing an aluminum (Al), a passivation layer 322 containing germanium (Ge), or the like.

As illustrated in FIG. 3E, in one or more embodiments, the passivation layer 322 is deposited using a soak process (e.g., a third soak process). The soak process may include soak the semiconductor device structure 300 in a processing chamber at a desired temperature, pressure, and time, such as the processing chambers 120, 122, 124, 126, 128, 130, or 132 as shown in FIG. 1, using a passivation layer precursor gas 326. In one or more embodiments, the passivation layer precursor gas 326 includes, but is not limited to, a Si containing soak gas precursor, a B containing soak gas precursor, an Al containing soak gas precursor, or a Ge containing soak gas precursor. Si containing soak gas precursors include, but are not limited to, silane (SiH₄), chlorosilane (SiH₃Cl), dichlorosilane (SiH₂Cl₂), trichlorosilane (SiHCl₃), silicon tetrachloride (SiCl₄), disilane (Si₂H₆), hexachlorodisilane (Si₂Cl₆), silicon hydrochlorides (Si₂HₓCl_{y} [x=0~6, y=0~6], or the like. B containing soak gas precursors include, but are not limited to, biborane (VI) (B₂H₆), boron trichloride (BCl₃), boron hydrochlorides (e.g., B₂HₓCl_{y} [x=0~6, y=0~6]), or the like. Al containing soak gas precursors include, but are not limited to, Trimethylaluminium (TMA), Triethylaluminum (TEA), or the like. In other embodiments, Ge containing soak gas precursor include, but are not limited to, germanium(IV) hydride (GeH₄).

The passivation layer precursor gas 326 permeates over the top surface 320t of the metal fill material 320 as well as penetrate the gaps 321. The passivation layer precursor gas 326 is absorbed by the outer surface of the metal fill material 320, forming the passivation layer 322. Stated otherwise, the passivation layer 322 surrounds all previously exposed surfaces of the metal fill material 320, and thus embeds the metal fill material 320 in the passivation layer 322. The chemistry of the passivation layer 322 depends on the precursor gas. Si based precursor gases form a passivation layer 322 containing Si. Boron (B) based precursor gases form a passivation layer 322 containing boron. Aluminum (Al) based precursor gases form a passivation layer 322 containing aluminum. Germanium (Ge) based precursor gases form a passivation layer 322 containing germanium. Optionally, in one or more embodiments, a preclean process may be performed prior to depositing the passivation layer 322 to improve formation of the passivation layer 322, as discussed in Operation 208. The preclean treatment can be a treatment process such as chemical soak process using WF₆ or MoCl₅ as the precursor gas 324.

In one or more examples, the third soak process may be performed at a chamber pressure of between about 1 Torr and about 100 Torr. The third soak process may include flowing the passivation layer precursor gas 326 in the presence of a carrier gas, such as argon (or another noble gas), at flow rate between about 5 sccm and about 2000 sccm, for example, 500 sccm. The soak process may be performed for a period of time between 1 second and 1500 seconds, such as 600 seconds. The third soak process may be performed at a process chamber temperature of between about 200° C. and about 500° C., for example, 450° C.

At operation 212, an overburden layer 328 is deposited at a second deposition rate. FIG. 3G illustrates a cross-sectional view of the semiconductor device structure 300 during intermediate stages of manufacturing corresponding to the operation 212. As shown in FIG. 3G, the overburden layer 328 is deposited in the feature 306 such that it fills the remainder of the feature 306. Suitable methods for depositing the overburden layer 328 include CVD processes, ALD processes, PECVD processes, physical vapor deposition (PVD), PEALD processes, or the like. An overburden layer 328 CVD and/or PECVD deposition process may include concurrently flowing (co-flowing) a precursor gas, and a reducing agent. In at least one embodiment, co-flowing a precursor gas and a reducing agent can comprise alternating sequential repetitions of exposing the device substrate 302 to the precursor gas, and the reducing agent. The overburden layer 328 ALD and/or PEALD process may include sequential repetitions of exposing the device substrate 302 to a precursor gas, then exposing the device substrate 302 to a reducing agent. The ALD and/or PEALD may further include purging the processing volume between exposing the device substrate 302 to the precursor gas, and the reducing agent by flowing an inert gas thereinto. In one or more examples, the precursor gas includes, but is not limited to, tungsten hexafluoride (WF₆), molybdenum(V) chloride, or combinations thereof, and the reducing agent includes, but is not limited to, hydrogen (H₂). In one or more embodiments, the overburden layer 328 may be the same material or different material than the metal fill material 320 In one or more embodiments, the overburden layer 328 may include a metal, including, but not limited to, Mo, Co, Cu, W, Ta, Ti, Ru, or combinations thereof. In one or more examples, the overburden layer 328 deposition process is a conformal deposition process that fills the feature 306 (e.g., covers the passivation layer 322) and covers the upper surface 304u of dielectric layer 304.

In one or more embodiments, prior to depositing the overburden layer 328, a nucleation layer may be formed on the surface of the passivation layer 322. In one embodiment, the nucleation layer is formed on the metal fill material 320. In one or more examples, the nucleation layer is formed over the top surface 320t of the metal fill material 320, the passivation layer 322, the upper surface 304u, and the exposed sidewalls 306s of the dielectric layer 304 within the feature 306. The nucleation layer may be formed using any suitable deposition process such as ALD, CVD, PEALD, PECVD, or the like. The nucleation layer may be used to promote the initiation, growth and adhesion (e.g., promote conformal deposition) of the subsequently formed overburden layer 328 to the dielectric layer 304 and the passivation layer 322 that would not otherwise occur.

In other embodiments, a barrier layer (not shown) may be deposited prior to the deposition of the overburden layer 328. In one or more examples, the barrier layer is formed over the top surface 320t of the metal fill material 320, the passivation layer 322, the upper surface 304u, and the exposed sidewalls 304s of the dielectric layer 304 within the feature 306. In one or more examples the barrier layer may include a metal material such as tantalum, titanium, cobalt, or the like. The barrier layer may be used to promote the initiation, growth and adhesion (e.g., conformal deposition) of the overburden layer 328 over the dielectric layer 304 and the metal fill material 320 that would not otherwise occur. The barrier layer may be formed using any suitable deposition process such as ALD, CVD, PEALD, PECVD, or the like. In one or more embodiments, the nucleation layer may be deposited over the barrier layer or the barrier layer may function as the nucleation layer.

In one or more embodiments, operation 212 is optional, and the method 200 may proceed to operation 214 after the deposition the metal fill material 320 and the treatment process during operation 208.

At operation 214, a chemical mechanical polishing (CMP) process is performed on the semiconductor device structure 300. FIG. 3H illustrates a cross-sectional view of the semiconductor device structure 300 during intermediate stages of manufacturing corresponding to the operation 214. In one or more embodiments, the CMP process is used for planarizing the semiconductor device structure 300. Stated otherwise, the CMP process planarizing the semiconductor device structure 300 includes removing portions of the upper surface 304u of the dielectric layer 304 until the passivation layer 322 and the field region are flush. Stated otherwise, the first depth D1 is reduced to a second depth D2 to the remove of portions of the upper surface 304u. In some embodiments, the second depth D2 formed during operation 214 is substantially equal to the height of the metal fill material 320 after performing operation 214. In one example, a thickness of the passivation layer 322 of between 1 and 50 angstroms (Å) remains over the top surface of the metal fill material 320 to assure that the surfaces of the metal fill material 320 remain encapsulated. In some embodiments, the second depth D2 formed during operation 214 is greater than the height of the metal fill material 320 after performing operation 210, such that a portion of the overburden layer 328 and the passivation layer 322 remain within the feature. In one example, a thickness of the overburden layer 328 of between 1 and 2000 angstroms (Å) remains over the top surface of the passivation layer 322 to assure that the material of the overburden layer 328, which is in good contact with the dielectric layer 304 due to the non-selective conformal deposition process used to form the overburden layer 328, prevents gases or other contaminants from entering any of the remaining open space within the gaps 321 and the surfaces of the metal fill material 320 remain encapsulated. In one or more embodiments, if the overburden layer 328 is deposited (operation 212), the overburden layer 328 (and any other intervening layers such as the nucleation layer and/or the barrier layer) are removed by the CMP process. In other embodiments, if the overburden layer 328 is not deposited, only portions of the upper surface 304u are removed.

Embodiments described herein generally relate to semiconductor device fabrication. More specifically, embodiments of the present disclosure relate to methods of removing metal oxides during semiconductor device manufacturing. During manufacturing, oxidation and/or nitridation occurs within the feature of the semiconductor device. The oxidation and/or nitridation may occur during a vacuum break or as a result of reactions with the processing gases. The oxidation and/or nitridation may form an oxide layer or a nitride layer in the feature and/or over the metal fill layer, which increases the resistance of the formed interconnect, and therefore, reduces the performance of the electrical connection. Described herein are various methods for removing the metal oxide layer (or metal nitride layer) within the feature with a pretreatment process such as a first chemical soak and treatment process such as a second chemical soak. The pretreatment and/or treatment processes include(s) soaking the semiconductor device in WF₆ or MoCl₅ during the manufacturing process to selectively etch the metal oxide, such as MoOx, or metal nitride without etching the feature. In addition to selectively etching the metal oxide or metal nitride, the treatment process and treatment process increase surface absorption, avoid side wall damage, increase resistance, and are capable of reaching the deep structure of the feature.

While the foregoing is directed to embodiments of the present disclosure, other and further embodiments of the disclosure may be devised without departing from the basic scope thereof, and the scope thereof is determined by the claims that follow.

What is claimed is:

1. A method of filling a semiconductor device structure, comprising:
performing a first soak process on the semiconductor device structure comprising at least one feature formed in a dielectric layer of the semiconductor device structure, the first soak process comprising:
flowing a first precursor gas over the at least one feature;
forming a metal fill material in the at least one feature, wherein:
the metal fill material partially fills the at least one feature, and
a gap region is formed between a sidewall of the at least one feature and the metal fill material; and
performing a second soak process on the semiconductor device structure, the second soak process comprising:
flowing a second precursor gas over the at least one feature and the metal fill material.

2. The method of claim 1, further comprising depositing an overburden layer in the at least one feature, the overburden layer filling a remainder of the at least one feature and covering a field region of the dielectric layer.

3. The method of claim 1, further comprising:
forming a passivation layer over the metal fill material and within the gap region.

4. The method of claim 3, wherein the passivation layer is a silicon (Si) containing passivation layer, a boron (B) containing passivation layer, an aluminum (Al) containing passivation layer, or a germanium (Ge) containing passivation layer.

5. The method of claim 1, wherein flowing the first precursor gas over the at least one feature further comprises flowing the first precursor gas into a processing chamber for about 60 seconds to about 180 seconds with a flow rate of about 500 sccm to about 1500 sccm, the processing chamber maintaining a temperature of 200°C. to about 400°C and a pressure of about 5 Torr to about 50 Torr.

6. The method of claim 1, wherein flowing the second precursor gas over the at least one feature further comprises flowing the second precursor gas into a processing chamber for about 60 seconds to about 180 seconds with a flow rate of about 500 sccm to about 1500 sccm, the processing chamber maintaining a temperature of 200°C. to about 400°C. and a pressure of about 5 Torr to about 50 Torr.

7. The method of claim 1, wherein the first precursor gas comprises tungsten hexafluoride (WF₆) and the second precursor gas comprises WF₆ or molybdenum (V) chloride (MoCl₅).

8. A method of filling a semiconductor device structure, comprising:
performing a first soak process on the semiconductor device structure comprising a feature formed within a dielectric layer of the semiconductor device structure, the first soak process comprising:
flowing a first precursor gas over the feature, the first precursor gas comprising tungsten hexafluoride (WF₆);
forming a metal fill material in the feature, wherein:
the metal fill material partially fills the feature, and
a gap region is formed between a sidewall of the feature and the metal fill material;
performing a second soak process on the semiconductor device structure, the second soak process comprising:
flowing a second precursor gas over the feature and the metal fill material, the second precursor gas comprising WF₆ or molybdenum (V) chloride (MoCl₅); and
forming a passivation layer over the feature, the passivation layer disposed over the metal fill material and within the gap region.

9. The method of claim 8, further comprising depositing an overburden layer in the feature, the overburden layer filling a remainder of the feature and covering a field region of the dielectric layer.

10. The method of claim 8, wherein the metal fill material comprises at least one of:
molybdenum (Mo), tungsten (W), cobalt (Co), copper (Cu), or ruthenium (Ru).

11. The method of claim 8, further comprising at least one vacuum break prior to performing the second soak process.

12. The method of claim 8, wherein flowing the first precursor gas over the feature comprises flowing the first precursor gas into a processing chamber for about 60 seconds to about 180 seconds with a flow rate of about 500 sccm to about 1500 sccm, the processing chamber maintaining a temperature of 200°C. to about 400°C. and a pressure of about 5 Torr to about 50 Torr.

13. The method of claim 8, wherein flowing the second precursor gas over the feature further comprises flowing the second precursor gas into a processing chamber for about 60 seconds to about 180 seconds with a flow rate of about 500 sccm to about 1500 sccm, the processing chamber maintaining a temperature of 200°C. to about 400°C. and a pressure of about 5 Torr to about 50 Torr.

14. The method of claim 8, wherein forming the passivation layer over the feature further comprises a soak process, wherein the soaking process comprises flowing a third precursor gas into a processing chamber for about 1 seconds to about 1500 seconds at a flow rate of about 5 sccm to about 2000 sccm, the processing chamber maintaining a pressure of 1 Torr to about 100 Torr and a temperature of 200°C. to about 500°C.

15. The method of claim 8, wherein the passivation layer is a silicon (Si) containing passivation layer, a boron (B) containing passivation layer, an aluminum (Al) containing passivation layer, or a germanium (Ge) containing passivation layer.

16. A semiconductor device structure, comprising:
a first dielectric layer disposed over a substrate;
a second dielectric layer disposed over the first dielectric layer;
a feature formed through the first dielectric layer and the second dielectric layer;
an electrical connection disposed within the feature;
a metal fill material disposed over the electrical connection; and
a passivation layer embedding the metal fill material.

17. The semiconductor device structure of claim 16, further comprising an etch stop layer disposed between the first dielectric layer and the second dielectric layer.

18. The semiconductor device structure of claim 16, wherein the passivation layer is disposed over a top surface of the metal fill material and gaps formed between sidewalls of the second dielectric layer and the metal fill material within the feature.

19. The semiconductor device structure of claim 16, wherein the metal fill material comprises at least one of: molybdenum (Mo), tungsten (W), cobalt (Co), copper (Cu), or ruthenium (Ru).

20. The semiconductor device structure of claim 16, wherein the passivation layer is a silicon (Si) containing passivation layer, a boron (B) containing passivation layer, an aluminum (Al) containing passivation layer, or a germanium (Ge) containing passivation layer.
